(19) United States
(12) Patent Application Publication
(10) Pub. No.: US 2025/0287608 A1
(43) Pub. Date: Sep. 11, 2025

(54) PILLAR CRITICAL DIMENSION REDUCTION BY ISOTROPIC PLASMA ETCHING WITH HIGH SELECTIVITY TO SILICON-CONTAINING ANTIREFLECTIVE COATING AND SILICON NITRIDE

(71) Applicants: International Business Machines Corporation, Armonk, NY (US); Tokyo Electron Limited, Tokyo (JP)

(72) Inventors: Luxherta Buzi, Chappaqua, NY (US); Devi Koty, Fishkill, NY (US); Hien Nguyen, Ocean, NJ (US); Robert L. Bruce, White Plains, NY (US)

(21) Appl. No.: 18/599,876

(22) Filed: Mar. 8, 2024

(51) Int. Cl. H10B 61/00; G01R 33/09; H01L 21/027; H01L 21/3105; H10B 63/10; H10N 50/01; H10N 50/10

(52) U.S. Cl. CPC H10B 61/22; G01R 33/098; H01L 21/0276; H01L 21/31058; H10B 63/10; H10N 50/01; H10N 50/10

(57) ABSTRACT

Provide an initial structure comprising a substrate, a hard mask outward of the substrate, a sacrificial organic layer outward of the hard mask, an anti-reflective coating outward of the sacrificial organic layer, and a patterned photoresist outward of the anti-reflective coating. Etch the initial structure to remove portions of the sacrificial organic layer and the anti-reflective coating not protected by the patterned photoresist down to the hard mask, to form sacrificial organic layer pillars under the patterned photoresist. Trim a critical dimension (CD) of the sacrificial organic layer pillars by etching with a gas that is selective to the anti-reflective coating and the hard mask, to trim sidewalls of the sacrificial organic layer pillars.

### BACKGROUND

The present invention relates generally to semiconductor devices, and more specifically, to semiconductor fabrication techniques and resultant structures.

A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds.

Continued progress in computing has led to a search for larger, faster memories, for applications such as hybrid cloud computing and the like. One such memory is three-dimensional crosspoint non-volatile memory (NVM).

### BRIEF SUMMARY

Principles of the invention provide techniques for pillar critical dimension (CD) reduction by isotropic plasma etching with high selectivity to silicon-containing antireflective coating (SiARC) and silicon nitride (SiN). In one aspect, an exemplary method includes providing an initial structure including a substrate, a hard mask outward of the substrate, a sacrificial organic layer outward of the hard mask, an anti-reflective coating outward of the sacrificial organic layer, and a patterned photoresist outward of the anti-reflective coating; etching the initial structure to remove portions of the sacrificial organic layer and the anti-reflective coating not protected by the patterned photoresist down to the hard mask, to form sacrificial organic layer pillars under the patterned photoresist; and trimming a critical dimension (CD) of the sacrificial organic layer pillars by etching with a gas that is selective to the anti-reflective coating and the hard mask, to trim sidewalls of the sacrificial organic layer pillars.

In another aspect, an exemplary magnetoresistive random access memory (MRAM) array includes: a plurality of bit lines and a plurality of complementary bit lines forming a plurality of bit line-complementary bit line pairs; a plurality of word lines intersecting the plurality of bit line pairs at a plurality of cell locations; and a plurality of magnetic tunnel junction cells located at each of the plurality of cell locations. Each of the magnetic tunnel junction cells is electrically connected to a corresponding bit line and selectively interconnected to a corresponding one of the complementary bit lines under control of a corresponding one of the word lines, and each of the plurality of magnetic tunnel junction cells includes: a bottom electrode; a top electrode; and a free magnetic layer and a pinned magnetic layer, with a tunnel barrier therebetween, located between the top and bottom electrodes. The free magnetic layer, the pinned magnetic layer, and the tunnel barrier have coextensive sidewalls that are parallel to within ±2 degrees.

In still another aspect, an exemplary phase change memory (PCM) array includes: a plurality of bit lines; a plurality of word lines intersecting the plurality of bit lines at a plurality of grid points; and a plurality of phase change memory (PCM) cells located at the plurality of grid points. Each phase change memory (PCM) cell of the plurality of phase change memory (PCM) cells is electrically connected to a corresponding bit line and selectively grounded under control of a corresponding one of the word lines. Each phase change memory (PCM) cell includes a top electrode, a phase change material (e.g., GST (germanium-antimony-tellurium or Ge2Sb2Te5)), and a bottom electrode. The top electrode and the phase change material have coextensive sidewalls that are parallel to within ±2 degrees.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-4 show successive steps in a fabrication process, in accordance with aspects of the invention; and

FIGS. 5-7 show scanning electron microscope (SEM) images corresponding respectively to FIGS. 1-3, in accordance with aspects of the invention;

FIG. 8 shows a magnetoresistive random access memory (MRAM) cell fabricated in accordance with aspects of the invention;

FIG. 9 shows a phase-change memory (PCM) cell fabricated in accordance with aspects of the invention;

FIG. 10 shows an array of magnetoresistive random access memory (MRAM) cells fabricated in accordance with aspects of the invention; and

FIG. 11 shows an array of phase-change memory (PCM) cells fabricated in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), in aspects of the invention an exemplary method includes providing an initial structure including a substrate 1001, a hard mask 1003 outward of the substrate, a sacrificial organic layer 1005 outward of the hard mask, an anti-reflective coating 1007 outward of the sacrificial organic layer, and a patterned photoresist 1009 outward of the anti-reflective coating. A further step includes etching the initial structure to remove portions of the sacrificial organic layer 1005 and the anti-reflective coating 1007 not protected by the patterned photoresist 1009 down to the hard mask 1003, to form sacrificial organic layer pillars under the patterned photoresist 1009. Still a further step includes trimming a critical dimension (CD) of the sacrificial organic layer pillars by etching with a gas that is selective to the anti-reflective coating and the hard mask, to trim sidewalls of the sacrificial organic layer pillars.

Technical benefits include providing a structure with pillars with highly parallel walls that can be used in the subsequent fabrication of MRAM or PCM with cells that have highly parallel walls. It is advantageous to be able to maintain a certain CD and to have highly parallel walls in the end product. If the stack is etched and the walls are tapered, the density of devices that can be achieved will be limited as they will occupy more space. In addition to the parallel walls, which enables higher density of cells, the reduction in CD compensates for lithography limitations—further reduction of CD beyond what can be achieved by lithography can be achieved by using exemplary method steps.

It is worth noting that the sacrificial organic layer can be used as a sacrificial layer for patterning.

It is worth noting that in the etching with the gas that is selective to the anti-reflective coating and the hard mask, the etching is highly selective, in the sense that the sputtering rate of materials such as SiN and SiARC is insignificant, so that it cannot be measured. That is, in one or more embodiments, material that is not etched does not suffer any measurable sputtering or degradation. For example, Optical Emission Spectroscopy (OES) does not indicate any signal or rise in emitted particles and/or when checking thickness with SEM or Transmission Electron Microscopy (TEM), there is no detectable thickness change.

In one or more embodiments, in the providing step, the sacrificial organic layer of the initial structure includes an organic planarization layer (OPL). Technical benefits include carrying out exemplary processes with commonly available material such as OPL.

In one or more embodiments, in the providing step, the sacrificial organic layer of the initial structure includes an amorphous carbon layer. Technical benefits include carrying out exemplary processes with commonly available material such as amorphous carbon.

In one or more embodiments, in the providing step, the anti-reflective coating of the initial structure includes silicon-containing antireflective coating (SiARC). Technical benefits include carrying out exemplary processes with commonly available material such as SiARC.

In one or more embodiments, in the providing step, the hard mask includes silicon nitride (SiN). Technical benefits include carrying out exemplary processes with commonly available material such as SiN.

In one or more embodiments, in the trimming step, the etching gas includes a plasma. Technical benefits include enhanced etch rate control.

For example, the plasma includes a carrier gas that is non-reactive to the sacrificial organic layer and a gas selected from the group consisting of carbon dioxide and carbon monoxide. Technical benefits include enhanced results compared to other plasmas.

For example, the carrier gas is selected from the group consisting of argon, neon, helium, xenon, and nitrogen. Technical benefits include enhanced results compared to other carrier gases.

For example, the plasma includes argon, nitrogen, and carbon dioxide. Technical benefits include best results compared to other plasmas.

In one or more embodiments, the trimming is carried out for 5 to about 400 seconds. Technical benefits include enhanced results compared to other time ranges.

In one or more embodiments, the trimming is carried out at a temperature in the range from about 40° C. to about 200° C. Technical benefits include enhanced results compared to other temperature ranges.

In one or more embodiments, the trimming is carried out at a pressure in the range from 4 mTorr to about 100 mTorr. Technical benefits include enhanced results compared to other pressure ranges.

In one or more embodiments, in the trimming step, the etching includes inductively coupled plasma etching. Technical benefits include ability to carry out the process with a commonly available etching machine such as an inductively coupled plasma etching machine.

In one or more embodiments, in the trimming step, the etching includes capacitively coupled plasma etching. Technical benefits include ability to carry out the process with a commonly available etching machine such as a capacitively coupled plasma etching machine.

In one or more embodiments, in the trimming step, the etching includes electron cyclotron resonance plasma etching. Technical benefits include ability to carry out the process with a commonly available etching machine such as an electron cyclotron resonance plasma etching machine.

In another aspect, a magnetoresistive random access memory (MRAM) array includes: a plurality of bit lines 1210 and a plurality of complementary bit lines 1208 forming a plurality of bit line-complementary bit line pairs; a plurality of word lines 1206 intersecting the plurality of bit line pairs at a plurality of cell locations; and a plurality of magnetic tunnel junction cells 1202 located at each of the plurality of cell locations. Each of the magnetic tunnel junction cells is electrically connected to a corresponding bit line and selectively interconnected to a corresponding one of the complementary bit lines under control of a corresponding one of the word lines. Each of the plurality of magnetic tunnel junction cells includes: a bottom electrode 701; a top electrode 711; and a free magnetic layer 709 and a pinned magnetic layer 705, with a tunnel barrier 707 therebetween, located between the top and bottom electrodes. The free magnetic layer, the pinned magnetic layer, and the tunnel barrier have coextensive sidewalls that are parallel to within ±2 degrees.

Technical benefits include an array with parallel sides and a small critical dimension allowing a dense array.

In one or more embodiments, the coextensive sidewalls are parallel to within ±1 degree. Technical benefits include an even denser array.

One or more embodiments further include an anti-ferromagnetic layer 703 between the bottom electrode and the pinned magnetic layer; the coextensive sidewalls include sides of the anti-ferromagnetic layer 703. Technical benefits include facilitating the use of an anti-ferromagnetic layer in a structure with parallel sides and a small critical dimension allowing a dense array.

In still another aspect, a phase change memory (PCM) array includes: a plurality of bit lines 1310; a plurality of word lines 1306 intersecting the plurality of bit lines at a plurality of grid points; and a plurality of phase change memory (PCM) cells located at the plurality of grid points. Each phase change memory (PCM) cell of the plurality of phase change memory (PCM) cells is electrically connected to a corresponding bit line 1310 and selectively grounded under control of a corresponding one of the word lines 1306. Each phase change memory (PCM) cell includes a top electrode 809, a phase change material 811/807 (e.g., GST (germanium-antimony-tellurium or Ge2Sb2Te5)), and a bottom electrode 803. The top electrode and the phase change material have coextensive sidewalls that are parallel to within ±2 degrees.

Technical benefits include an array with parallel sides and a small critical dimension allowing a dense array.

In one or more embodiments, the coextensive sidewalls are parallel to within ±1 degree. Technical benefits include an even denser array.

Techniques as disclosed herein can provide substantial beneficial technical effects. Some embodiments may not have these potential advantages and these potential advantages are not necessarily required of all embodiments. By way of example only and without limitation, in addition to those discussed above, one or more embodiments may provide one or more of providing ability to achieve larger, faster memories, for applications such as hybrid cloud computing and the like, such as a three-dimensional crosspoint non-volatile memory (NVM) or the like using a complex and thick stack of materials, where features need to be scaled to a small critical dimension (CD); and/or ability to shrink the CD (e.g., width), while preserving integrity, sidewall shape, and/or SiARC/bottom hard mask.

As noted above, continued progress in computing has led to a search for larger, faster memories, for applications such as hybrid cloud computing and the like. One such memory is three-dimensional crosspoint non-volatile memory (NVM). Implementation of 3D cross-point technology requires a complex and thick stack of materials, and features need to be scaled to a small critical dimension (CD). Dry etching is advantageously used to achieve this in one or more embodiments. First, print the features using lithography. Then, etch the layers down. One or more embodiments operate at the top of the stack, where the soft mask is etched. One or more embodiments etch the first two layers, SiARC and OPL (Organic Planarization Layer). In one or more instances, first transfer the CD from the photoresist to the SiARC, by etching the SiARC. Then, etch the OPL. Normally, when etching the OPL, the CD is transferred essentially one-to-one from the SiARC to the OPL. However, there are limits to the CD that can be printed with lithography. One or more embodiments advantageously enable shrinking the CD, by using etching to shrink the OPL sidewall with high selectivity to the top SiARC and the bottom hard mask (the bottom hard mask can be, e.g., SiN), while preserving integrity, sidewall shape, and SiARC/bottom hard mask.

Thus, aspects of the invention provide pillar critical dimension (CD) (e.g., width) reduction by isotropic plasma etching with high selectivity to SiARC and SiN. One or more embodiments facilitate continued progress in computing by providing larger, faster memories, for applications such as hybrid cloud computing and the like, using three-dimensional crosspoint non-volatile memory (NVM).

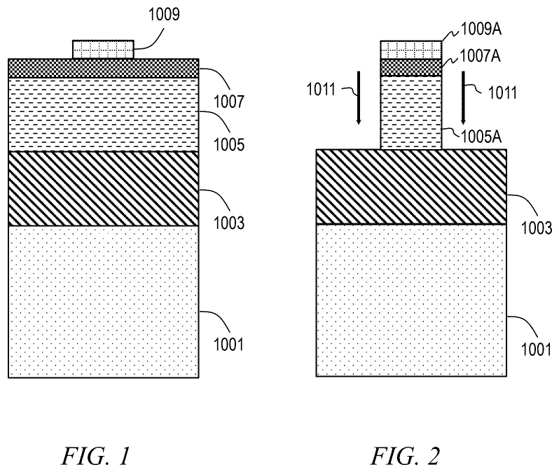

FIGS. 1 and 5 show a starting structure. The stack of FIG. 1 includes: silicon substrate 1001, SiN 1003, OPL (Organic Planarization Layer) 1005, SiARC 1007, and photo resist (PR) 1009 that has been patterned. Such a structure can be produced using known deposition and lithographic techniques

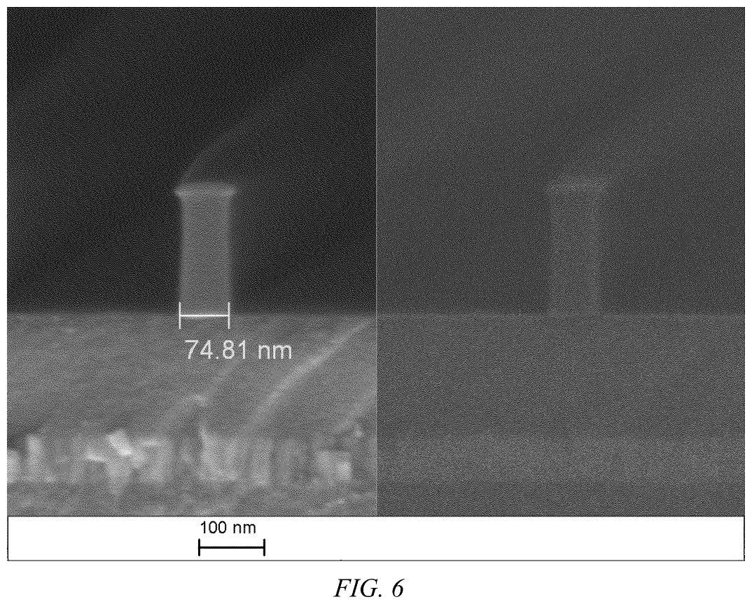

FIGS. 2 and 6 show the structure of FIGS. 1 and 5 after downward etching of the SiARC using an etchant such as CHF₃/CF₄, followed by downward etching of the OPL using an etchant such as Ar/N₂/CH₄/O₂. For example, reactive ion etching (RIE) can be utilized for these operations in one or more embodiments. The downward etching is suggested by the arrows 1011. The OPL and SiARC after etching are designated as 1005A, 1007A. The PR after etching is designated as 1009A and will typically be shorter than the original PR 1009.

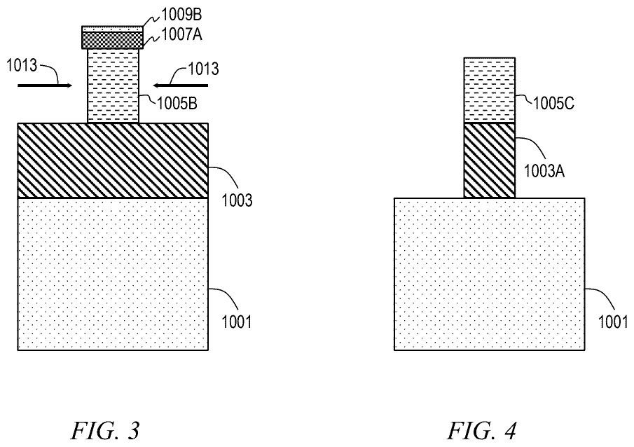

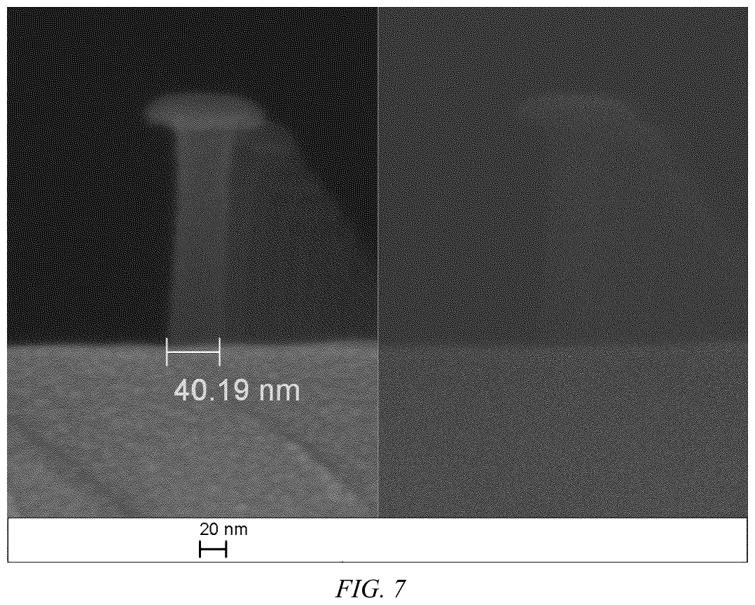

FIGS. 3 and 7 show the structure of FIGS. 2 and 6 after using CO₂ and inert chemistry (e.g., Ar/N₂/CO₂) to trim the CD of the pillar of OPL. The trimming is suggested by the arrows 1013. The trimmed pillar of OPL is referred to as 1005B. The SiARC after trimming is still designated as 1007A since it will typically retain its original dimensions, and the PR after trimming is designated as 1009B and is typically thinner than 1009A. The gas mixture for the isotropic plasma etching can have a range of ratios of different constituents. There will typically be a carrier gas with a higher flow rate than the other constituents. Various known plasma etching chambers can be used, as will be apparent to the skilled artisan, given the teachings herein. Generally, exemplary processes can be performed in any type of RIE chamber (Inductively Coupled Plasma Etching (ICP RIE), Capacitively Coupled Plasma Etching (CCP), electron cyclotron resonance (ECR) plasma etching, etc.) at a temperature in the range 40-200° C. at a range of about 4-100 millitorr (mTorr) for a time in a range of about 5-400 seconds(s), using carrier gas (e.g., Ar, Ne, He, Xe, N) that is inert/non-reactive to the organic layer.

One or more embodiments thus enable shrinking the CD at the OPL level for pillars, etching the OPL in a manner that is highly selective to the SiARC 1007B and the SiN hard mask 1003. In one or more embodiments, short (see example time range above) plasma pulses containing Ar/N₂/CO₂ are applied to permit the isotropic etching of the OPL pillars, with high selectivity to the SiARC 1007B and the SiN hard mask 1003. Advantageously, the sidewalls of OPL 1005B typically remain straight after the exemplary trimming process.

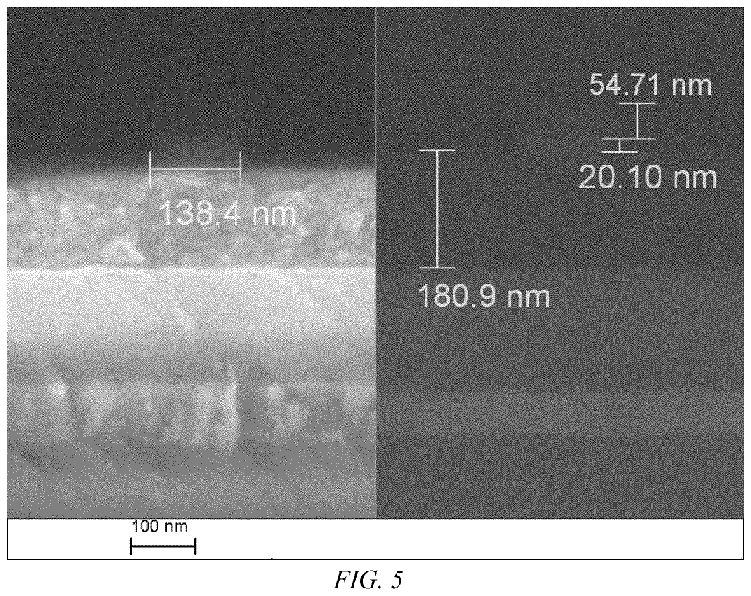

In one or more embodiments, during the trimming, Ar/N₂/CO₂ plasma etches the sidewalls of the OPL (Organic Planarization Layer) pillars 1005B so as to maintain a straight profile (see discussion of parallelism below). In one or more embodiments, the plasma mixture has a uniform lateral etch rate/isotropic etch rate to the OPL layer. Generally, low bias power plasma techniques can be employed and the uniform etch rate is intrinsic to the gaseous mixture in the plasma as disclosed herein. Referring to FIG. 4, after the plasma etching in FIG. 3, the SiN hard mask 1003 is etched to have the same dimension as the OPL 1005B. By that time, the SiARC 1007A and resist 1009B have been removed and the OPL will be a bit shorter, and is thus designated as 1005C in FIG. 4. The etched SiN hard mask is designated as 1003A in FIG. 4.

Given the teachings herein, the skilled artisan will appreciate that etching/pillar techniques according to aspects of the invention can be used to fabricate a variety of structures, such as, for example, arrays of memory devices, such as non-volatile memory devices (magnetic RAM (MRAM) or phase change memory (PCM)). In one or more embodiments, the “super-straight” trimmed mask 1003A will produce a much straighter (as compared to conventional techniques) final product with straighter sidewall angles. Small pillars formed using technology other than embodiments of the invention will be much more tapered than those formed using aspects of the invention.

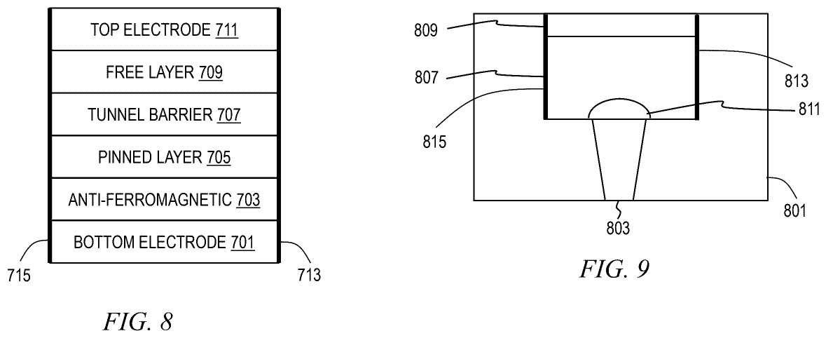

FIG. 8 shows an MRAM cell formed using aspects of the invention. Note the bottom electrode 701, optional anti-ferromagnetic layer 703, pinned layer 705, tunnel barrier 707 (e.g., MgO), free layer 709, and top electrode 711. Note that the electrodes are not necessarily separate structures but generally can be conductive material (e.g., metal such as copper or the like) that can be a separate structure or part of a metal line, metal via, etc. The free layer and pinned layer can be formed of known magnetic materials. The optional anti-ferromagnetic layer 703 can be formed, for example, from two ferromagnetic layers separated by a non-magnetic coupling spacer layer. When formed in accordance with one or more embodiments, the sidewalls 713, 715 of the stack are parallel to within ±2 degrees or even within ±1 degree whereas the skilled person would not expect to be able to achieve ±2 degrees or ±1 degree parallelism with known techniques. Given the teachings herein, the skilled artisan can form cells such as that depicted in FIG. 8 from the structure depicted in FIG. 4, where the cell can be formed in the substrate 1001 and will have sides that correspond to the spacing and parallelism of the sides of the pillars 1003A, 1005C.

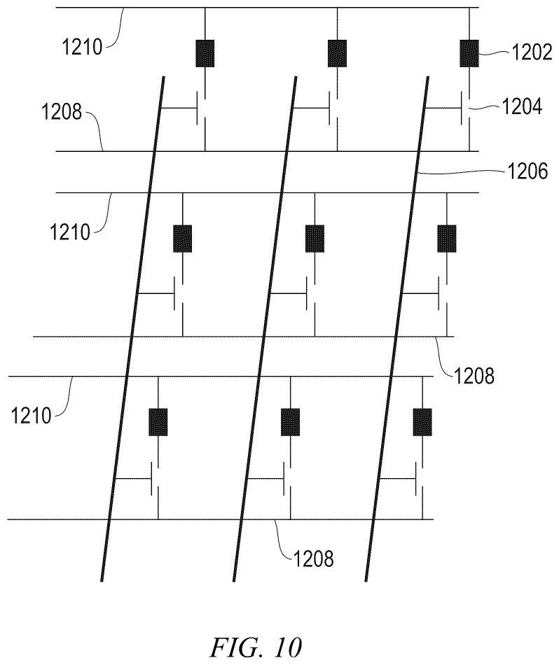

FIG. 10 shows an MRAM array with a plurality of bit lines 1210 and a plurality of complementary bit lines 1208 forming a plurality of bit line-complementary bit line pairs. A plurality of word lines 1206 intersect the plurality of bit line pairs at a plurality of cell locations. A plurality of MRAM cells 1202, such as that of FIG. 8, are located at each of the plurality of cell locations, and are connected as shown through the electrodes. Each of the magnetic tunnel junction cells 1202 is electrically connected to a corresponding bit line 1210 and selectively interconnected to a corresponding one of the complementary bit lines 1208 under control of a corresponding one of the word lines 1206 (e.g., a respective transistor 1204 is a field effect transistor turned off or on by a signal from word line 1206 applied to its gate, which controls reading and writing and whether the cell is coupled to the complementary bit lines).

As will be appreciated by the skilled artisan, peripheral circuitry (not shown) can be coupled to the plurality of bit line-complementary bit line pairs and the plurality of word lines; a power supply (not shown) and a controller (not shown) can be coupled to the power supply and the peripheral circuitry. The power supply can be controlled by the controller to supply appropriate voltages, and can be part of the controller or a separate unit. These elements are cooperatively configured for input/output and so on. Given the teachings herein, the skilled artisan will be able to provide any additional desired/required peripheral circuitry, voltage/power supply, elements to interface with peripheral circuitry, and the controller by adapting known techniques. To implement digital circuitry for a controller or the like, computer-aided semiconductor integrated circuit (IC) logic design, simulation, test, layout, and/or manufacture can be employed. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques.

In one or more embodiments, the peripheral circuitry, the power supply, and the controller are cooperatively configured to apply signals to the word lines 1206 to cause a first subset of the cells 1202 to first logical values, and a second subset of the cells 1202 to store second logical values. The first and second logical values are different (e.g., 1 and 0). The peripheral circuitry, the power supply, and the controller are further cooperatively configured to read the first and second stored logical values via the bit lines 1210 and the complementary bit lines 1208.

FIG. 9 shows a PCM cell formed using aspects of the invention. In one or more embodiments, the PCM cell includes a top electrode 809, a phase change material 811/807 (e.g., GST (germanium-antimony-tellurium or Ge₂Sb₂Te₅)), and a bottom electrode 803. The phase change material 811/807 can include a first portion 811 and/or a second portion 807 depending on its state. It should be understood that GST is useful as a medium of storage or memory given its ability to affect a reversible phase change when heated and cooled rapidly, or heated slowly, switching between an amorphous state and a crystalline state. According to one or more embodiments, the first portion of GST 811 is an amorphous state GST and the second portion of GST 807 is a crystalline state GST. The portion 811 may be electrically programmed to a crystalline state GST. It should be understood that portions 811/807 are the same material, and that the presence of portion 811 depends on the state of the device (i.e., if the GST is amorphized into RESET (high resistance), then portion 811 is present). The PCM cell is disposed in dielectric layer 801 (e.g., silicon). When formed in accordance with one or more embodiments, the sidewalls 813, 815 of the elements 807, 809 are parallel to within ±2 degrees or even within ±1 degree whereas the skilled person would not expect to be able to achieve ±2 degrees or ±1 degree parallelism with known techniques. Given the teachings herein, the skilled artisan can form cells such as that depicted in FIG. 9 from the structure depicted in FIG. 4, where the cell can be formed in the substrate 1001 and will have sides that correspond to the spacing and parallelism of the sides of the pillars 1003A, 1005C.

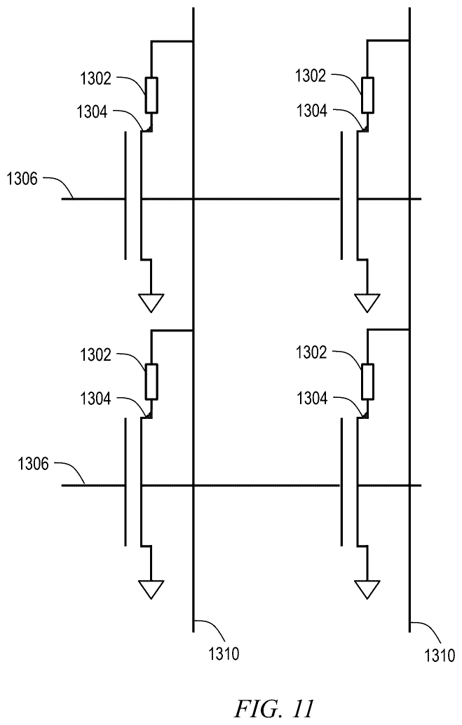

FIG. 11 shows a PCM array with a plurality of bit lines 1310 and a plurality of word lines 1306 that intersect the plurality of bit lines at a plurality of cell locations. A plurality of PCM cells 1302, such as that of FIG. 9, are located at each of the plurality of cell locations and connected through the electrodes. Each of the cells 1302 is electrically connected to a corresponding bit line 1310 and selectively grounded under control of a corresponding one of the word lines 1306 (e.g., a respective transistor 1304 is a field effect transistor turned off or on by a signal from word line 1306 applied to its gate, in a known manner).

As will be appreciated by the skilled artisan, appropriate peripheral circuitry (not shown) and a suitable controller (not shown), can be provided. Given the teachings herein, the skilled artisan will be able to provide any additional desired/required peripheral circuitry, voltage supply, elements to interface with peripheral circuitry, and a controller by adapting known techniques.

It is worth noting that the cells of FIGS. 8 and 9 and the arrays of FIGS. 10 and 11 are shown at a high level of generality, it being understood that a pertinent aspect is the fabrication of the cells with highly parallel walls as described herein and that other aspects can be implemented by adapting known techniques.

FIGS. 8 and 9 are simplified for convenience, but real-world devices may require (many) additional layers as would be apparent to the skilled artisan—the complexity of the stack may also depend on the configuration of the cell. For example, the stack in FIG. 8 could include one or more seed layers for growing the layers 705 and/or 709; the layer 703 could be multiple layers such as Ru sandwiched between layers of Co/Pt, and so on.

Referring to the SEM image of FIG. 5, note the 138.4 nm width and 54.71 nm thickness of the PR 1009; the 20.10 nm thickness of the SiARC 1007; the 180.9 nm thickness of the OPL 1005. In the SEM image of FIG. 6, the pillar has a width of 74.81 nm. In the SEM image of FIG. 7, the pillar has a width of 40.19 nm with the PR 1009B and SiARC 1007B forming a “mushroom cap” on the top.

One or more embodiments thus provide a process of trimming the CD of an OPL pillar for a patterning structure including SiARC on top and SiN at the bottom. One step includes applying Ar/N₂/CO₂ plasma to trim a sidewall of an OPL layer to reduce its CD, as per FIGS. 3 and 7. In one or more embodiments, the OPL and SiARC have been etched beforehand, as per FIGS. 2 and 6.

In some cases, Ar/N₂/CO₂ plasma is used to trim the OPL sidewall with high selectivity to the top SiARC and bottom SiN, as in FIGS. 3 and 7.

In some cases, Ar/N₂/CO₂ plasma is used to trim the OPL sidewall and maintain a straight OPL profile, as in FIGS. 3 and 7.

It is worth noting that conventional aspects of semiconductor fabrication will now be described at a high level of generality, it being understood that a pertinent aspect is the fabrication of the cells with highly parallel walls as described herein and that other aspects can be implemented by adapting conventional techniques. Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system; for example, where larger, faster memories are desired for applications such as hybrid cloud computing and the like (e.g., MRAM, PCM, three-dimensional crosspoint NVM). Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A method comprising:
providing an initial structure comprising a substrate 1001, a hard mask 1003 outward of the substrate, a sacrificial organic layer 1005 outward of the hard mask, an anti-reflective coating 1007 outward of the sacrificial organic layer, and a patterned photoresist 1009 outward of the anti-reflective coating;
etching the initial structure to remove portions of the sacrificial organic layer 1005 and the anti-reflective coating 1007 not protected by the patterned photoresist 1009 down to the hard mask 1003, to form sacrificial organic layer pillars under the patterned photoresist 1009; and
trimming a critical dimension (CD) of the sacrificial organic layer pillars by etching with a gas that is selective to the anti-reflective coating and the hard mask, to trim sidewalls of the sacrificial organic layer pillars.

2. The method of claim 1, wherein, in the providing step, the sacrificial organic layer of the initial structure comprises an organic planarization layer (OPL).

3. The method of claim 1, wherein, in the providing step, the sacrificial organic layer of the initial structure comprises an amorphous carbon layer.

4. The method of claim 1, wherein, in the providing step, the anti-reflective coating of the initial structure comprises silicon-containing antireflective coating (SiARC).

5. The method of claim 4, wherein, in the providing step, the hard mask comprises silicon nitride (SiN).

6. The method of claim 5, wherein, in the trimming step, the etching gas comprises a plasma.

7. The method of claim 6, wherein the plasma includes a carrier gas that is non-reactive to the sacrificial organic layer and a gas selected from the group consisting of carbon dioxide and carbon monoxide.

8. The method of claim 7, wherein the carrier gas is selected from the group consisting of argon, neon, helium, xenon, and nitrogen.

9. The method of claim 6, wherein the plasma includes argon, nitrogen, and carbon dioxide.

10. The method of claim 9, wherein the trimming is carried out for 5 to about 400 seconds.

11. The method of claim 10, wherein the trimming is carried out at a temperature in the range from about 40° C. to about 200° C.

12. The method of claim 11, wherein the trimming is carried out at a pressure in the range from 4 mTorr to about 100 mTorr.

13. The method of claim 6, wherein, in the trimming step, the etching comprises inductively coupled plasma etching.

14. The method of claim 6, wherein, in the trimming step, the etching comprises capacitively coupled plasma etching.

15. The method of claim 6, wherein, in the trimming step, the etching comprises electron cyclotron resonance plasma etching.

16. A magnetoresistive random access memory (MRAM) array comprising:
a plurality of bit lines and a plurality of complementary bit lines forming a plurality of bit line-complementary bit line pairs;
a plurality of word lines intersecting the plurality of bit line pairs at a plurality of cell locations;
a plurality of magnetic tunnel junction cells located at each of the plurality of cell locations, each of the magnetic tunnel junction cells being electrically connected to a corresponding bit line and selectively interconnected to a corresponding one of the complementary bit lines under control of a corresponding one of the word lines, each of the plurality of magnetic tunnel junction cells comprising:
a bottom electrode;
a top electrode; and
a free magnetic layer and a pinned magnetic layer, with a tunnel barrier therebetween, located between the top and bottom electrodes;
wherein the free magnetic layer, the pinned magnetic layer, and the tunnel barrier have coextensive sidewalls that are parallel to within ±2 degrees.

17. The magnetoresistive random access memory (MRAM) array of claim 16, wherein the coextensive sidewalls are parallel to within ±1 degree.

18. The magnetoresistive random access memory (MRAM) array of claim 17, further comprising an anti-ferromagnetic layer 703 between the bottom electrode and the pinned magnetic layer, wherein the coextensive sidewalls include sides of the anti-ferromagnetic layer 703.

19. A phase change memory (PCM) array comprising:
a plurality of bit lines 1310;
a plurality of word lines 1306 intersecting the plurality of bit lines at a plurality of grid points; and
a plurality of phase change memory (PCM) cells located at the plurality of grid points;
wherein:
each phase change memory (PCM) cell of the plurality of phase change memory (PCM) cells is electrically connected to a corresponding bit line 1310 and selectively grounded under control of a corresponding one of the word lines 1306;
each phase change memory (PCM) cell includes a top electrode 809, a phase change material 811/807 (e.g., GST (germanium-antimony-tellurium or Ge2Sb2Te5)), and a bottom electrode 803; and
the top electrode and the phase change material have coextensive sidewalls that are parallel to within ±2 degrees.

20. The phase change memory (PCM) array of claim 19, wherein the coextensive sidewalls are parallel to within ±1 degree.
